(19) United States
(12) Patent Application Publication
(10) Pub. No.: US 2026/0245833 A1
(43) Pub. Date: Aug. 20, 2026

(54) MULTI-ZONE RF FOR WAFER EDGE PLASMA PROFILE TUNING

(71) Applicant: Applied Materials, Inc., Santa Clara, CA (US)

(72) Inventors: Jian Li, Fremont, CA (US); Ganesh Balasubramanian, Fremont, CA (US); Juan Carlos Rocha-Alvarez, San Carlos, CA (US); Edward P. Hammond, Hillsborough, CA (US); Madhu Santosh Kumar Mutyala, San Jose, CA (US); Yuanchang Chen, Santa Clara, CA (US)

(73) Assignee: Applied Materials, Inc., Santa Clara, CA (US)

(21) Appl. No.: 19/055,656

(22) Filed: Feb. 18, 2025

(51) Int. Cl. H01J 37/32; C23C 16/505; C23C 16/52; H01L 21/02

(52) U.S. Cl. CPC H01J 37/32183; C23C 16/505; C23C 16/52; H01J 37/32137; H01J 37/32715; H01J 2237/2007; H01J 2237/3321; H10P 14/6336

(57) ABSTRACT

Internal meshes may causes a material discontinuity at the edge of a silicon wafer at a transition to the material of the pedestal. This causes a corresponding discontinuity in the RF power delivered to the plasma and consequently in the plasma profile. To solve this problem, one or more external meshes may be added around the periphery of the pedestal around the substrate. These external meshes may be individually coupled to variable impedances or variable RF sources. A controller may adjust the variable impedances and/or RF sources in order to tune the plasma profile around the edge of the substrate. This allows plasma-enhanced processes to provide a uniform plasma profile over the substrate, resulting in consistent and uniform process.

### TECHNICAL FIELD

This disclosure generally describes methods and systems for tuning plasma profiles during plasma-based semiconductor manufacturing processes. More specifically, this disclosure describes pedestal mesh and circuit designs for tuning plasma profiles at an edge of a semiconductor substrate during plasma deposition or etch processes.

### BACKGROUND

In the field of semiconductor manufacturing, the application of plasma-enhanced processes has emerged as a critical technique for improving the efficiency and quality of material deposition. These processes leverage ionized gases to create highly reactive species that can facilitate the growth of thin films, etch substrates, and modify surface properties. As semiconductor devices continue to shrink in size and increase in complexity, the uniformity of the plasma profile across the substrate has become paramount. Variability in plasma distribution can lead to inconsistencies in layer thickness, composition, and overall performance, ultimately affecting the reliability of semiconductor devices.

The challenge of achieving a uniform plasma profile is compounded by the intricate geometries and diverse materials used in semiconductor fabrication. Traditional methods of plasma generation may produce nonuniform distributions due to variations in gas flow dynamics, electromagnetic fields, or substrate positioning. These inconsistencies can result in patchy deposition, where certain areas of the substrate receive significantly different treatments than others. Such disparities not only degrade the material properties of the deposited films but also increase the risk of defects, thereby undermining the performance and yield of semiconductor devices. To address these issues, there is a need for innovative approaches that enhance plasma uniformity across the substrate surface.

### SUMMARY

In some embodiments, a semiconductor processing chamber may include a pedestal configured to support a substrate during a plasma-enhanced process performed on a substrate. The chamber may also include one or more internal meshes embedded in the pedestal. The one or more internal meshes may be configured to deliver radio-frequency (RF) power to a plasma in the semiconductor processing chamber during the plasma-enhanced process. The chamber may additionally include one or more RF sources configured to deliver the RF power to the one or more internal meshes, one or more external meshes embedded in the pedestal that encircle the one or more internal meshes, and one or more variable impedances coupled to the one or more external meshes that tune a plasma profile at an edge of the substrate.

In some embodiments, a method of tuning plasma profiles during semiconductor processes may include supporting a substrate on a pedestal in a semiconductor processing chamber. The semiconductor processing chamber may be configured to perform a plasma-enhanced chemical-vapor deposition (PECVD) process that forms a film on a surface of the substrate. The method may also include providing a precursor to a semiconductor processing chamber, wherein the precursor comprises a material for the film to be formed on the substrate, forming a plasma from the precursor in the semiconductor processing chamber, delivering RF power to plasma through one or more internal meshes embedded in the pedestal, and adjusting one or more variable impedances coupled to one or more external meshes to tune a plasma profile at an edge of the substrate.

In some embodiments, a semiconductor processing chamber may include a pedestal configured to support a substrate during a plasma-enhanced process performed on a substrate and one or more internal meshes embedded in the pedestal. The one or more internal meshes may be configured to deliver a first RF power to a plasma in the semiconductor processing chamber during the plasma-enhanced process. The chamber may also include one or more first RF sources configured to deliver the first RF power to the one or more internal meshes, one or more external meshes embedded in the pedestal that encircle the one or more internal meshes, and one or more second RF sources coupled to the one or more external meshes. A phase difference between the one or more first RF sources and the one or more second RF sources may be adjustable to tune a plasma profile at an edge of the substrate.

In any embodiments, any and all of the following features may be implemented in any combination and without limitation. A controller may be programmed to adjust the one or more variable impedances during the plasma-enhanced process to adjust the RF power delivered to the one or more internal meshes and the one or more external meshes to tune the plasma profile at the edge of the substrate. An outer diameter of the one or more internal meshes may be less than a diameter of the substrate such that the substrate entirely covers the one or more internal meshes when supported by the pedestal. The one or more external meshes together may have a ring shape divided into a plurality of sectors that encircles the one or more internal meshes. An inner diameter of the one or more external meshes may be greater than a diameter of the substrate such that the substrate does not cover the one or more external meshes when supported by the pedestal. The one or more internal meshes may be a single mesh that also functions as a monopolar electrostatic chuck. The one or more internal meshes may include a two hemispherical meshes that also function as a bipolar electrostatic chuck. The one or more external meshes may include three or more meshes that do not function as an electrostatic chuck. The one or more external meshes may be electrically coupled to ground through the one or more variable impedances, such that adjusting the one or more variable impedances may tune an amount of the RF power provided to the one or more internal meshes that is shunted to ground through the one or more external meshes. The one or more external meshes may be electrically coupled to one or more second RF sources through the one or more variable impedances. The plasma-enhanced process may include a PECVD process that forms a film on a surface of the substrate. A variable impedance in the one or more variable impedances may include a variable capacitor with a range of between 0 nF and 100 nF. The RF power provided to the plasma may include a first frequency and a second frequency where the first frequency is higher than the second frequency. A variable impedance in the one or more variable impedances may include a variable capacitor in series with an inductor, and the variable impedance may be tuned to approximate an open circuit for the second frequency and a short-circuit for the first frequency. A variable impedance in the one or more variable impedances may include a variable capacitor in parallel with an inductor, and the variable impedance may be tuned to approximate an open circuit for the second frequency and a short-circuit for the first frequency. Adjusting the one or more variable impedances coupled to one or more external meshes to tune the plasma profile at the edge of the substrate may include adjusting the one or more variable impedances until a variation of the plasma profile at the edge of the substrate has a variation of less than 10% of a plasma profile at a center of the substrate. A characteristic of the plasma that is indicative of the plasma profile at the edge of the substrate may be monitored during the process, and the one or more variable impedances may be adjusted to tune a plasma profile at an edge of the substrate in response to monitoring the characteristic of the plasma until the plasma profile at the edge of the substrate is within a predetermined range during the process. A controller may be programmed to adjust the phase difference between the one or more first RF sources and the one or more second RF sources to tune a plasma profile at an edge of the substrate during the plasma-enhanced process. The phase difference between the one or more first RF sources and the one or more second RF sources may include the one or more first RF sources lagging behind the one or more second RF sources by 90°. The phase difference between the one or more first RF sources and the one or more second RF sources may include the one or more first RF sources lagging behind the one or more second RF sources by 180°.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 shows a schematic cross-sectional view of an exemplary processing chamber according to some embodiments of the present technology.

FIGS. 2A-2D illustrate diagrams of the pedestal and the placement of the meshes relative to the substrate, according to some embodiments.

FIGS. 3A-3D illustrate alternate configurations for the internal meshes when used as a monopolar chuck, according to some embodiments.

FIG. 4A illustrates an implementation of a semiconductor processing chamber, according to some embodiments.

FIG. 4B illustrates an implementation of a semiconductor processing chamber with a monopolar chuck, according to some embodiments.

FIG. 4C illustrates an implementation of a semiconductor processing chamber with a top-feed RF delivery system, according to some embodiments.

FIG. 5 illustrates an implementation of a bottom the processing chamber with a bipolar electrostatic chuck that couples the external meshes to RF power, according to some embodiments.

FIG. 6 illustrates an implementation of a bottom-feed processing chamber with a bipolar electrostatic chuck that couples the external meshes to separate RF power sources, according to some embodiments.

FIG. 7 illustrates different implementations for the variable impedances, according to some embodiments.

FIG. 8 illustrates a flowchart of a method of tuning plasma profiles during semiconductor processes, according to some embodiments.

FIG. 9 illustrates an exemplary computer system, in which various embodiments may be implemented.

### DETAILED DESCRIPTION

Existing pedestal designs utilize internal meshes to deliver RF power to the plasma. This causes a material discontinuity at the edge of the wafer, where the silicon of the substrate transitions to the aluminum nitride of the pedestal. This causes a corresponding discontinuity in the radio frequency (RF) power delivered to the plasma, and consequently causes the plasma profile to vary at the edge of the substrate. This causes film discontinuities and nonuniformity at the edge of the substrate compared to the center of the substrate. To solve this problem, one or more external meshes may be added around the periphery of the pedestal around the substrate. These external meshes may be individually coupled to variable impedances and/or variable RF sources. A controller may adjust the variable impedances and/or RF sources in order to tune the plasma profile around the edge of the substrate. This allows plasma-enhanced processes to provide a uniform plasma profile over the substrate, resulting in consistent and uniform depositions, etches, and so forth.

After describing general aspects of a chamber according to some embodiments of the present technology in which plasma processing operations discussed below may be performed, specific methodology may be discussed. It is to be understood that the present technology is not intended to be limited to the specific films, chambers or processes discussed, as the techniques described may be used to improve a number of film formation processes, and may be applicable to a variety of processing chambers and operations.

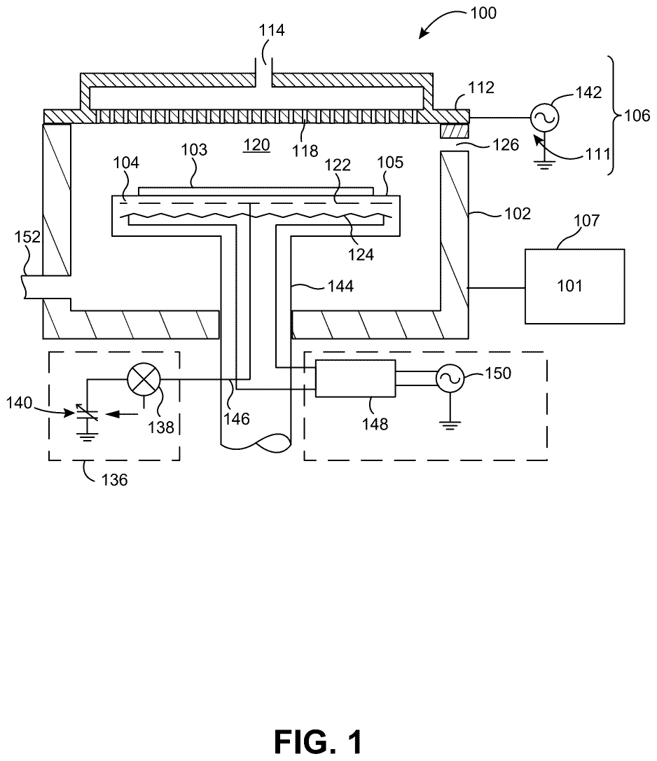

FIG. 1 shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers, etch material layers, form other material layers, or a combination thereof, although it is to be understood that deposition and etch methods may similarly be performed in any chamber within which deposition and etch processes may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. In some embodiments, the substrate support 104 may be rotatable, along a vertical axis, where a shaft 144 of the substrate support 104 may be located, or may be stationary. Alternatively, the substrate support 104 may be lifted up to rotate as necessary during a deposition process.

A gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

A first electrode 122 may be coupled with the substrate support 104. The first electrode 122 may be embedded within the substrate support 104 or coupled with a surface of the substrate support 104. The first electrode 122 may be a plate, a perforated plate, a mesh, a wire screen, or any other distributed arrangement of conductive elements. The first electrode 122 may be a tuning electrode and may be coupled with a tuning circuit 136 by a conduit 146, for example a cable having a selected resistance, such as 50 ohms, for example, disposed in the shaft 144 of the substrate support 104. The tuning circuit 136 may have an electronic sensor 138 and an electronic controller 140, which may be a variable capacitor. The electronic sensor 138 may be a voltage or current sensor and may be coupled with the electronic controller 140 to provide further control over plasma conditions in the processing volume 120.

A second electrode 124, which may be a bias electrode and/or an electrostatic chucking electrode, may be coupled with the substrate support 104. The second electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the processing chamber 100 may afford real-time control of plasma conditions in the processing volume 120, such as via a system controller 101 which may be contained within a processor 107. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the second electrode 124 in some embodiments.

Upon energizing a plasma in the processing volume 120, a potential difference may be established between the plasma and the first electrode 122. The electronic controller 140 may then be used to adjust the flow properties of the ground paths represented by the tuning circuit 136. A set point may be delivered to the tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Tuning circuit 136 may have a variable impedance that may be adjusted using the electronic controller 140. Where the electronic controller 140 is a variable capacitor, the capacitance range of each of the variable capacitors, may be chosen to provide an impedance range. This range may depend on the frequency and voltage characteristics of the plasma, which may have a minimum in the capacitance range of each variable capacitor. Hence, when the capacitance of the electronic controller 140 is at a minimum or maximum, impedance of the tuning circuit 136 may be high, resulting in a plasma shape that has a minimum aerial or lateral coverage over the substrate support. When the capacitance of the electronic controller 140 approaches a value that minimizes the impedance of the tuning circuit 136, the aerial coverage of the plasma may grow to a maximum, effectively covering the entire working area of the substrate support 104. As the capacitance of the electronic controller 140 deviates from the minimum impedance setting, the plasma shape may shrink from the chamber walls and aerial coverage of the substrate support may decline.

The electronic sensor 138 may be used to tune the tuning circuit 136 in a closed loop. A set point for current or voltage, depending on the type of sensor used, may be installed in each sensor, and the sensor may be provided with control software that determines an adjustment to the electronic controller 140 to minimize deviation from the set point. Consequently, a plasma shape may be selected and dynamically controlled during processing. It is to be understood that, while the foregoing discussion is based on electronic controller 140, which may be a variable capacitor, any electronic component with adjustable characteristic may be used to provide tuning circuit 136 with adjustable impedance.

Processing chamber 100 may be utilized in some embodiments of the present technology for processing methods that may include bottom-up deposition of materials for semiconductor structures. It is to be understood that the chamber described is not to be considered limiting, and any chamber that may be configured to perform operations as described may be similarly used.

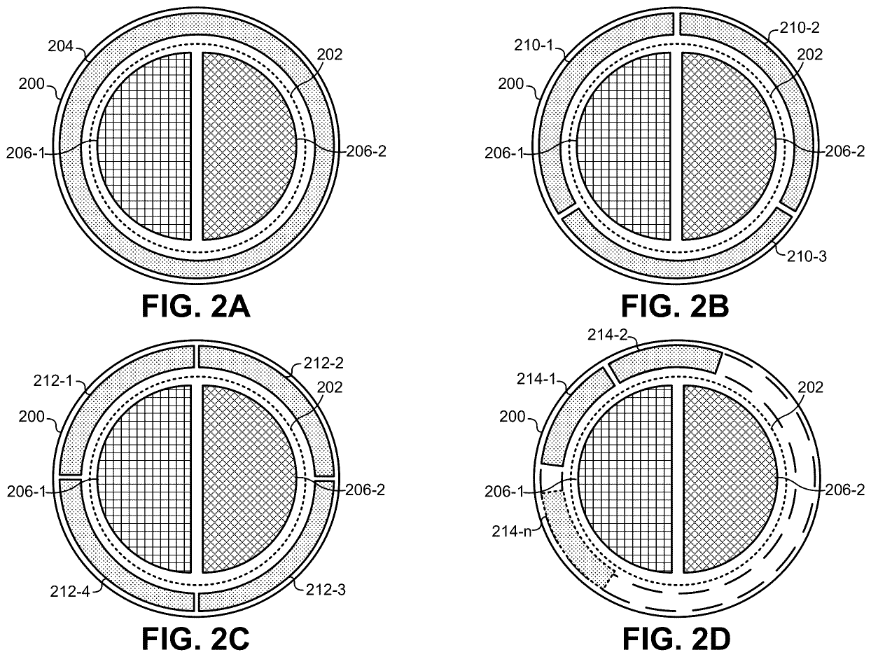

FIGS. 2A-2D illustrate diagrams of the pedestal and the placement of the meshes relative to the substrate, according to some embodiments. As described above, existing pedestal designs utilize internal meshes to deliver RF power to the plasma. This causes a material discontinuity at the edge of the wafer, where the silicon of the substrate transitions to the aluminum nitride of the pedestal. This causes a corresponding discontinuity in the radio frequency (RF) power delivered to the plasma, and consequently causes the plasma profile to vary at the edge of the substrate. This causes film discontinuities and nonuniformity at the edge of the substrate compared to the center of the substrate. To solve this problem, one or more external meshes may be added around the periphery of the pedestal around the substrate.

The pedestal 200 may include one or more internal meshes 206. In the examples of FIGS. 2A-2D, the one or more internal meshes 206 may include a first internal mesh 206-1 and a second internal mesh 206-2. However, these configurations are provided only by way of example and are not meant to be limiting. Other embodiments may include three or more internal meshes. These internal meshes may have any geometric configuration. In this example, the internal meshes 206 may be shaped as hemispherical meshes (e.g., half circles) that are separated by a space in the center of the pedestal 200. Since the internal meshes 206 may be embedded within the pedestal 200, this space separating the internal meshes 206 may be filled with a dielectric or other insulator such as aluminum nitride or another material from which the pedestal 200 may be manufactured. Other embodiments may include additional internal meshes and may divide these meshes into sectors (e.g., pie slices) that are equally spaced around the area under the substrate 202 and have a similar area. Some embodiments may instead use concentric rings that radiate outward from the center of the pedestal 200. The internal meshes 206 may be distinguished from external meshes in that the internal meshes may have an outer diameter that is less than a diameter of the substrate 202. This may result in the substrate entirely covering the one or more internal meshes 206 when the substrate 202 is supported by the pedestal 200. For example, the one or more internal meshes 206 may have a diameter that is less than a diameter of the substrate 202. The smaller diameter may cause the substrate 202 to completely cover the one or more internal meshes in the pedestal 200 as depicted in FIGS. 2A-2D. The edge of the substrate 202 may extend out beyond the diameter or edge of, for example, the first internal mesh 206-1. In other embodiments, the outer diameter of the internal meshes 206 may be approximately the same as a diameter of the substrate 202.

The distance between the outer edge of the substrate 202 and the outer diameter of the one or more internal meshes 206 may vary in different embodiments. For example, some embodiments may provide internal meshes 206 having a diameter that is approximately equal to the diameter of the substrate 202. Other embodiments may further reduce the outer diameter of the internal meshes such that the difference is greater than 0 mm. However, increasing the distance too much may reduce the strength of the electric field at the periphery of the substrate 202 and began to negatively affect the quality of the film being formed. Conversely, decreasing the size of the internal meshes can lead to inadequate chucking, especially for processes where wafer bow becomes more tensile as the process continues.

Some embodiments may size the outer diameter of the internal meshes such that the this diameter is less than the diameter of the substrate 202 by about 1 mm, about 2 mm, about 3 mm, about 4 mm, about 5 mm, about 6 mm, about 7 mm, about 8 mm, about 9 mm, about 10 mm, about 12 mm, about 15 mm, or greater, depending on characteristics of the chamber. In some embodiments, this difference may range from between about 0 mm and about 2 mm, between about 2 mm and about 5 mm, between about 5 mm and about 7 mm, between about 7 mm and about 10 mm, between about 10 mm and about 12 mm, between about 12 mm and about 15 mm, or greater and/or any combination of these ranges depending on the characteristics of the chamber. Other embodiments may size the internal meshes based on a diameter of the substrate 202. For example, some embodiments may size the outer diameter of the internal meshes to be between about 100% and about 98% of the diameter of the substrate 202. In other examples, the outer diameter of the internal meshes may be less than or between about 98% and about 96%, less than or between about 96% and about 95%, less than or between about 95% and about 94%, less than or between about 94% and about 93%, less than or between about 93% and about 92%, less than or between about 92% and about 90%, and less than about 90% and/or any combination of these ranges depending on the characteristics of the chamber.

The one or more internal meshes 206 may serve a dual purpose in some embodiments. For example, in addition to providing RF power to the plasma, the internal meshes 206 may also function as an electrostatic chuck. The configurations shown in FIGS. 2A-2D use the first internal mesh 206-1 and the second internal mesh 206-2 as positive/negative electrodes for a bipolar electrostatic chuck. Therefore, as internal meshes 206 may be selectively or electrically coupled to DC power supplies that provide electrostatic chucking voltages. Alternatively, additional chucking electrodes may be embedded in the pedestal 200 to provide an electrostatic chucking function that is separate from the RF delivery function provided by the internal meshes 206.

In addition to the internal meshes 206, the pedestal 200 may also include one or more external meshes that are also embedded in the pedestal 200. The external meshes may be arranged and sized such that they encircle the internal meshes 206. For example, the external meshes may together substantially form a ring shape with an inner and outer diameter as depicted in FIGS. 2A-2D. The external meshes may be subdivided into any number of meshes. For example, FIG. 2A illustrates a single external mesh 204 formed as a single ring around the internal meshes 206. FIG. 2B illustrates how the external meshes 210 may be subdivided into three individual meshes. The ring shape formed by the external meshes 210 may be subdivided into a plurality of sectors, which may be equally spaced and may have equal areas and/or geometries. Other embodiments may have unequal spacing and/or unequal areas as needed. FIG. 2C illustrates another example of how the external meshes 212 may be subdivided into four sectors or individual meshes. Note that any other arrangement or number of external meshes may be used in various embodiments. For example, the external meshes may be divided into two meshes forming half rings around the internal meshes 206. FIG. 2D illustrates how the external meshes may be subdivided into an arbitrary number of n meshes that are equally spaced and distributed around the exterior of the pedestal 200 to encircle the internal meshes 206.

Some embodiments may size the inner diameter of the external meshes such that the distance from the internal meshes 206 is about 1 mm, about 2 mm, about 3 mm, about 4 mm, about 5 mm, about 6 mm, about 7 mm, about 8 mm, about 9 mm, about 10 mm, about 12 mm, about 15 mm, or greater, depending on characteristics of the chamber. In some embodiments, the distance from the internal meshes 206 may range from between about 0 mm and about 2 mm, between about 2 mm and about 5 mm, between about 5 mm and about 7 mm, between about 7 mm and about 10 mm, between about 10 mm and about 12 mm, between about 12 mm and about 15 mm, or greater and/or any combination of these ranges depending on the characteristics of the chamber. Other embodiments may size the external meshes based on a diameter of the substrate 202. For example, some embodiments may size the inner diameter of the external meshes to be between about 100% and about 102% of the diameter of the substrate 202. In other examples, the inner diameter of the external meshes may be greater than or between about 102% and about 104%, greater than or between about 104% and about 105%, greater than or between about 105% and about 106%, greater than or between about 106% and about 107%, greater than or between about 107% and about 108%, greater than or between about 108% and about 110%, and greater than about 110% and/or any combination of these ranges depending on the characteristics of the chamber.

The outer diameter of the external meshes may be determined by a width of the external meshes. For example, a width of the external meshes (e.g., the distance between the internal and external diameters of the external meshes) may be between 5 mm about 10 mm, between about 10 mm and about 20 mm, between about 20 mm and about 30 mm, between about 30 mm and about 40 mm, between about 40 mm and about 50 mm, between about 50 mm about 60 mm, between about 60 mm and about 70 mm, between about 70 mm and about 80 mm, between about 80 mm about 90 mm, between about 90 mm and about 100 mm, and/or greater than about 100 mm. The width of the external meshes may also be characterized using any combination of the ranges described above (e.g., between about 20 mm and about 60 mm, greater than about 30 mm, etc.). The width of the external meshes may also be characterized using any single value in the ranges above (e.g., about 50 mm wide).

The term “mesh” may refer to any geometric arrangement of conductive material inside the pedestal 200. For example, the internal/external meshes may be formed from rectangular meshes or lattices of conductive copper wire. Other geometries for the mesh may be used, such as concentric circles, hexagon grids, circular meshes, and so forth. In some embodiments, the mesh may be formed from a solid sheet of material rather than from individual wires arranged into a ring or hemisphere.

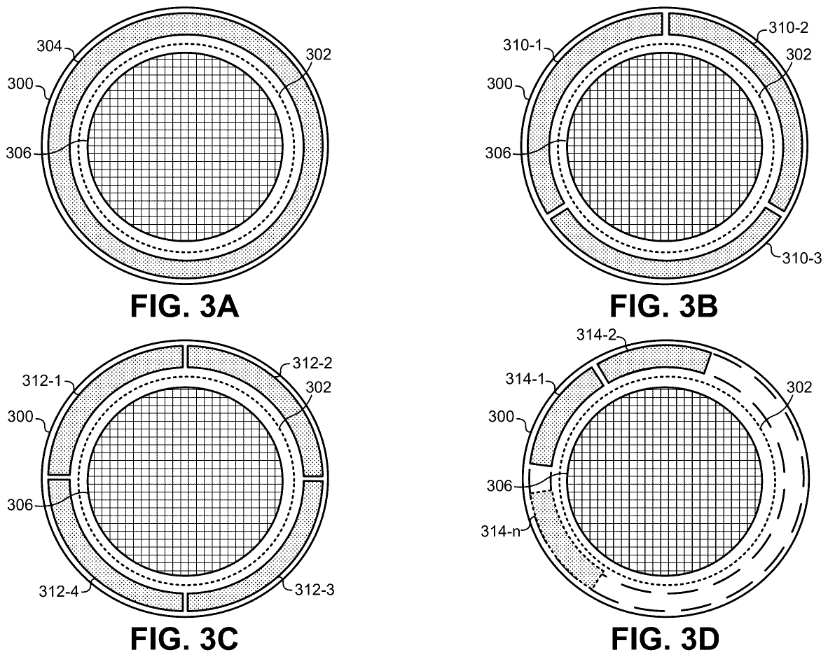

FIGS. 3A-3D illustrate alternate configurations for the internal meshes when used as a monopolar chuck, according to some embodiments. A monopolar chuck may apply a single DC voltage to an electrode in the pedestal 300, and the plasma may induce an opposing electric charge on the substrate 302 in order to clamp the substrate 302 onto the pedestal 300. These configurations are similar to those illustrated in FIGS. 2A-2D except that the one or more internal meshes now form a single internal mesh 306. For example, FIG. 3A illustrates a single external mesh 304 surrounding an internal mesh 306. FIG. 3B illustrates a plurality of external meshes 310 that have been subdivided into three sectors to surround the internal mesh 306. FIG. 3C illustrates four external meshes 312. FIG. 3D illustrates an arbitrary number n of external meshes 314 arranged to encircle the internal mesh 306. As described above, the external meshes in these configurations need not operate as an electrostatic chuck, but instead may be used to adjust the RF around the perimeter of the substrate 302 to tune the plasma profile. All of the measurements, configurations, geometries, locations, and other characteristics of the external meshes described above in FIGS. 2A-2D may also be applied to the meshes of FIGS. 3A-3D.

The external meshes may be used to adjust the RF profile around the perimeter of the substrate. As described above, the material mismatch between the silicon substrate and the pedestal may cause a discontinuity in the RF power profile above the edge of the substrate. This in turn may cause the plasma profile to be nonuniform at the edge of the substrate. A plasma profile in a semiconductor process may refer to the a number of characteristics of the plasma generated during processes such as etching or deposition. In these processes, gases are ionized to create a plasma, which may include ions, electrons, and neutral particles. The plasma profile may describe how these components are distributed spatially and temporally within the processing chamber. When referring to the “plasma profile,” this disclosure may refer to the combination of these different characteristics or to any individual characteristic of the plasma profile. For example, characteristics of the plasma profile may include the density or concentration of charged particles at various points within the plasma. The energy distribution or concentration of kinetic energy of the particles may be a characteristic of the plasma profile that affects the rate of reactions and deposition or etching. The plasma profile may also refer to the effective temperature of the plasma which influences the behavior of the ions and electrons. The plasma profile may also refer to the uniformity of the plasma across the substrate, including a plasma height (rather geometry) or a plasma envelope.

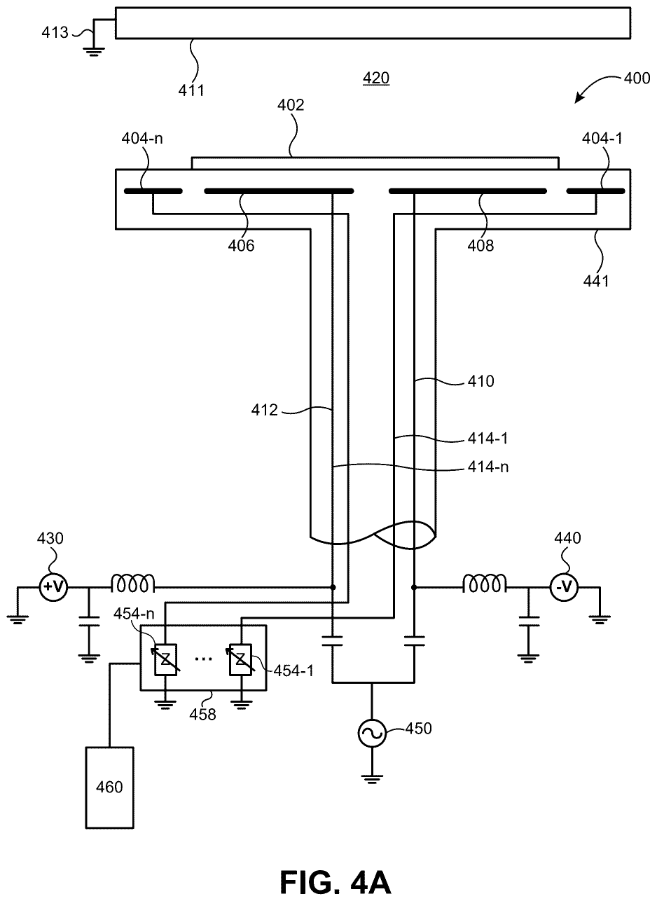

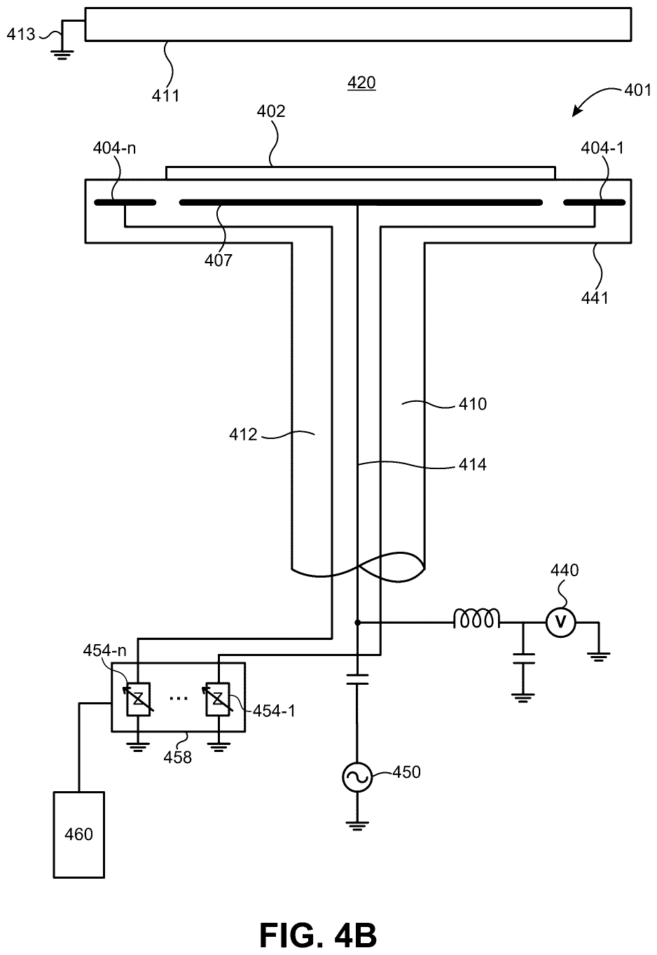

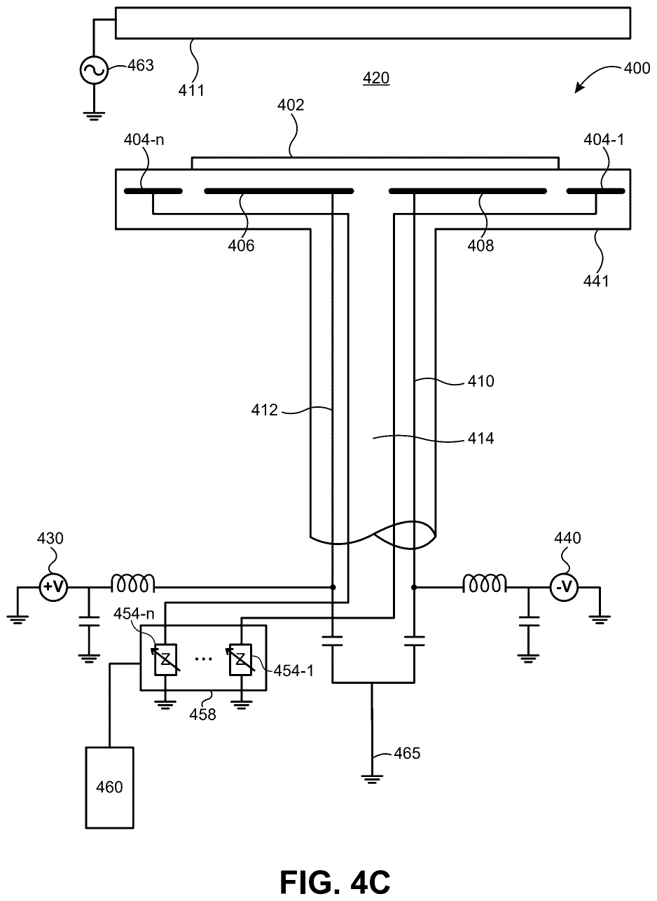

FIG. 4A illustrates an implementation of a semiconductor processing chamber 400, according to some embodiments. For example, the semiconductor processing chamber 400 may be a specific implementation of the processing chamber 100 illustrated above in FIG. 1. In some embodiments, the semiconductor processing chamber 400 may be specifically configured to perform chemical vapor deposition (CVD) on a substrate. Chemical vapor deposition is a process used to deposit thin films of material onto a substrate using a chemical reaction of vapor-phase precursor molecules. A precursor gas may be introduced into the semiconductor processing chamber 400 and subjected to elevated temperatures and/or pressures to form a solid film on a surface of the substrate.

Some embodiments of the CVD process may be enhanced using a plasma (PECVD). A PECVD process is a variation on the CVD process that forms a plasma in a processing region 420 of the semiconductor processing chamber 400 in order to enhance the film deposition and improve the properties of the deposited films. For example, the precursor gases may be introduced into the processing region 420 along with a carrier gas, such as nitrogen or argon. A plasma may then be formed with the precursor gas in a highly energized state of radicals, ions, and other species. The energetic ions of the plasma may disassociate from the precursor molecules such that they can more readily participate in the chemical reactions during the film deposition. Additionally, the plasma may generate highly reactive radicals (e.g., atomic hydrogen, atomic nitrogen, and so forth), which may also participate in surface reactions and affect the properties of the deposited films.

Chemical vapor deposition with a plasma may be used to deposit a wide range of materials, including ceramics, organic compounds, semiconductors, metals, and so forth. For example, the deposition of alternating oxide and/or nitride layers in an “ONO” stack may be used for various semiconductor devices. In another example, a relatively thick film of silicon oxide may be deposited using a precursor of tetraethyl orthosilicate (TEOS) over a semiconductor layer or over the ONO stack. However, these types of film depositions are provided only by way of example and are not meant to be limiting. The techniques described herein may be used to deposit any type film on a substrate. Additionally, other plasma-enhanced processes may also benefit from these techniques, including etch processes. Therefore, any of the embodiments described herein may also be used in conjunction with etching a material from a surface of a substrate.

In order to energize the plasma in the processing region 420, the semiconductor processing chamber 400 may include a pedestal 441 configured to hold a substrate 402 thereon. The pedestal 441 may include one or more radio-frequency (RF) meshes embedded within the pedestal 441. For example, as illustrated in FIG. 4A the pedestal 441 may include one or more internal meshes, such as a first internal mesh 406 and a second internal mesh 408. More generally, the pedestal 441 may include any of the internal and/or external mesh configurations described above in relation to FIGS. 2A-2D and FIGS. 3A-3D.

The first internal mesh 406 and the second internal mesh 408 may be coupled to one or more power sources that are programmed to provide RF power to the plasma in the processing region 420 and/or to provide an electrostatic chucking (ESC) force to hold the substrate 402 against the pedestal 441 during the deposition process. For example, the first internal mesh 406 may be coupled to a first lead 412 that extends out of the pedestal 441. The first lead 412 may be coupled to a first ESC source 430. The first ESC source 430 may include a DC voltage source that provides a DC voltage to a portion of the substrate 402 that is directly above the first internal mesh 406. An RF filter circuit may be placed between the first ESC source 430 and the first internal mesh 406. The RF filter circuit may include active or passive components, such as an inductor, resistors, and/or capacitors as illustrated in FIG. 4A. The RF filter circuit may be configured with components that filter out the RF frequencies that may be provided to or coupled to the first lead 412, for example, to protect the first ESC source 430.

Similarly, the second internal mesh 408 may be coupled to a second ESC source 440 that provides an opposing DC voltage relative to the first ESC source 430. For example, the second internal mesh 408 may be coupled to a second lead 410 that extends out of the pedestal 441. The potential difference between the first ESC source 430 and the second ESC source 440 may generate an electrostatic force that holds the substrate 402 to the pedestal 441. An RF filter circuit comprising inductors, resistors, and/or capacitors may be placed between the second lead 410 and the second ESC source 440 to filter out RF frequencies that may be present on the second lead 410.

The first lead 412 and/or the second lead 410 may also be coupled to one or more RF sources that are configured to deliver RF power to the one or more internal meshes in the pedestal 441. For example, a single RF source 450 may provide RF power to the first lead 412 and/or the second lead 410. In some embodiments, one or more capacitors may be coupled between the RF source 450 and the one or more internal meshes.

As described above, one technique for tuning the plasma profile over the substrate is to include one or more external meshes and to adjust various circuit components coupled to these meshes in order to regulate the RF power at the edge of the substrate. For example, the embodiment illustrated in FIG. 4A shows the first internal mesh 406 and the second internal mesh 408 described above. Additionally, some designs of the pedestal 441 may include one or more external meshes 404 that surround the one or more internal meshes. The external mesh(es) 404 may have a ring-shape that encircles the internal meshes as illustrated above. A gap or insulated area may separate the external mesh(es) 404 from the internal meshes, such that the external mesh(es) 404 are electrically isolated from the internal meshes. The external mesh(es) 404 may be implemented using a grid or other pattern of conductive wiring to form the ring-shape of the external mesh 404. Like the first internal mesh 406 and the second internal mesh 408, the external mesh(es) 404 may be coupled corresponding leads 414. The lead(s) 414 may exit the pedestal 441 and be coupled to corresponding variable impedances 454 that are between the external mesh 404 and a ground 458.

Although only two external meshes 404 are shown in FIG. 4A, this is not meant to be limiting. As described above in FIGS. 2A-2D, the system may include any number of external meshes, including one mesh, two meshes, three meshes, more than three meshes, four meshes, five meshes, and so forth. Each of these meshes may have corresponding leads that couple these meshes to corresponding variable impedances. In some embodiments, each mesh may be associated with a corresponding lead and variable impedance. In other embodiments, multiple meshes may share individual leads and/or variable impedances if needed.

FIG. 4B illustrates an implementation of a semiconductor processing chamber with a monopolar chuck, according to some embodiments. This implementation is similar to that of FIG. 4A, except that the internal mesh 407 is a singular internal mesh for a monopolar electrostatic chuck. This requires only a single ESC source 440 rather than a pair of internal meshes and a pair of ESC sources. However, the principle of operation using the one or more external meshes 404 still applies to this implementation. Specifically, a portion of the RF power delivered from the RF source 450 into the internal mesh 407 may be channeled away from the plasma to the ground 458 through the external meshes 404 and the variable impedances 454 in order to tune the plasma profile, including any of the plasma profile characteristics described above.

FIG. 4C illustrates an implementation of a semiconductor processing chamber with a top-feed RF delivery system, according to some embodiments. This implementation is similar to that of FIG. 4A, except that power is delivered through the top of the chamber 400 rather than through the pedestal. For example, an RF source may be coupled to a showerhead, distributor, or other top plate 411 of the chamber 400. The RF power may then be transmitted through the plasma to the internal meshes of the pedestal. A portion of the RF power may also be transmitted through the external meshes 404 through the variable impedances 454 to ground 458. The amount of power that is pulled through the external meshes 404 may be adjusted by adjusting the values of the variable impedances 454. As described above, this may change the plasma profile at the periphery of the substrate 402 as a result of changing the RF power at the periphery of the substrate 402.

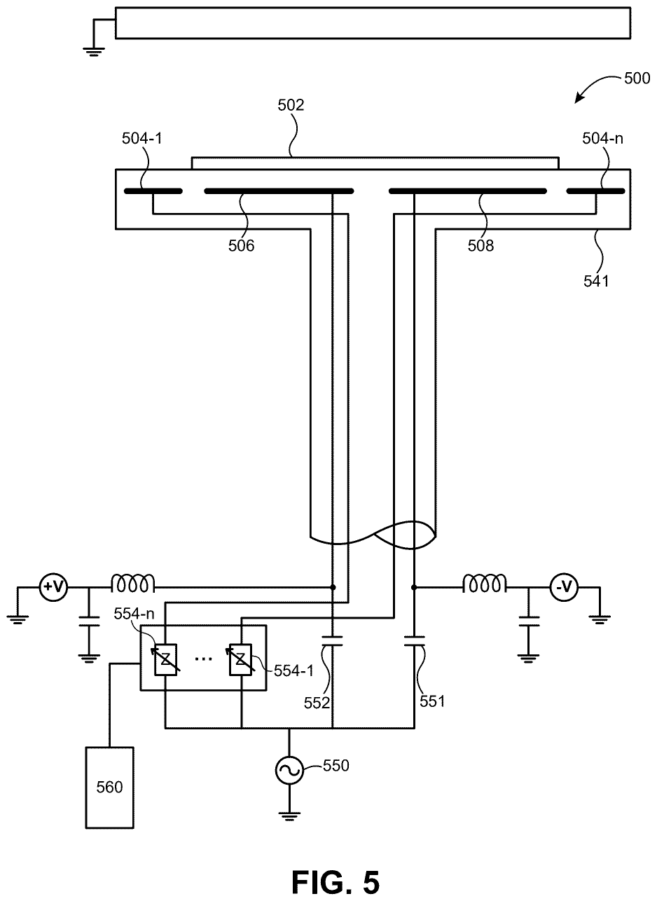

FIG. 5 illustrates an implementation of a bottom the processing chamber 500 with a bipolar electrostatic chuck that couples the external meshes to RF power, according to some embodiments. In this implementation, a single RF source 550 may be used to provide power to any and/or all of the meshes in the pedestal 441. For example, a first internal mesh 506 and a second internal mesh 508 may receive power from the RF source 550 through a pair of capacitors 551, 552. Similarly, the external meshes 504 may receive RF power through the variable impedances 554. Instead of adjusting the RF power at the periphery of the substrate 502 by siphoning a portion of the RF power back to ground through the external meshes 504, this implementation instead adjusts the relative power provided through the external meshes 504 compared to the internal meshes to adjust the total RF power above the substrate 502. For example, a controller 560 may adjust the values of the variable impedances 554 to adjust the amount of RF power provided to the external meshes 504 relative to the internal meshes. This in turn may be used to adjust the plasma profile at the edge of the substrate 502 as described above.

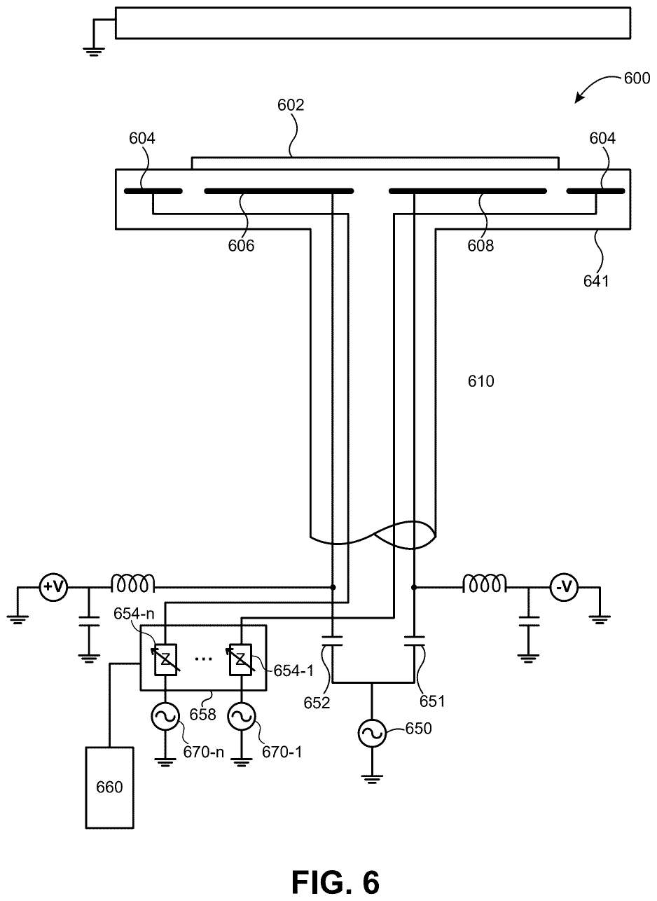

FIG. 6 illustrates an implementation of a bottom-feed processing chamber 600 with a bipolar electrostatic chuck that couples the external meshes to separate RF power sources, according to some embodiments. This implementation is similar to the chamber 500 of FIG. 5 except that the external meshes may be provided with individual programmable RF sources 670. The adjustable impedances 654 may be optional and may be included or replaced with fixed impedance values (e.g., a fixed capacitance). Instead, the amount of RF power delivered to the external meshes 604 may be regulated by changing the outputs of the programmable RF sources 670. For example, a first internal mesh 606 and a second internal mesh 608 may receive power from the RF source 650 through a pair of capacitors 651, 652. To distinguish the RF source 650 from other RF sources, it may be referred to as a “first” RF source. It multiple RF sources are used for each internal mesh, these may be referred to as one or more first RF sources. Similarly, the individual RF sources 670 provided to the external meshes 604 may be referred to as “second” RF sources. The external meshes 604 may receive RF power from the individual RF sources 670. Instead of adjusting the RF power at the periphery of the substrate 602 by siphoning a portion of the RF power back to ground through the external meshes 604, this implementation may instead adjust the relative power provided through the external meshes 604 compared to the internal meshes to adjust the total RF power above the substrate 602. For example, a controller 660 may adjust the outputs of the individual RF sources 670 in order to adjust the amount of RF power provided to the external meshes 604 relative to the internal meshes. This in turn may be used to adjust the plasma profile at the edge of the substrate 602 as described above.

In some embodiments, the RF source 650 may be shared between all of the internal meshes. Alternatively, other implementations may provide individual RF sources for each of the internal meshes. In other words, one or more first RF sources may be configured to deliver a first RF power to the one or more internal meshes. Similarly, some embodiments may allow some of the individual programmable RF sources 670 to be shared between various external meshes 604. Other embodiments may provide individual programmable RF sources 650 for each of the external meshes 604. In other words, one or more second RF sources may be coupled to the one or more external meshes.

In order to tune the plasma profile at the edge of the substrate during a plasma-enhanced process, some embodiments may adjust a phase difference between the RF sources 764 the external meshes 604 and the RF source(s) for the internal meshes. For example, allowing the voltage phase of the RF source 650 to lead or lag behind the voltage phase of the RF sources 670 may adjust the relative RF power between the internal and external meshes at the edge of the substrate 602. This may in turn adjust the plasma profile at the edge of the substrate as described above. For example, the voltage phase of the RF source 650 may lead or lag behind the RF sources 670 by 90°, by 180°, or by other values determined experimentally or in real time using the process described below for monitoring the plasma profile during the plasma process.

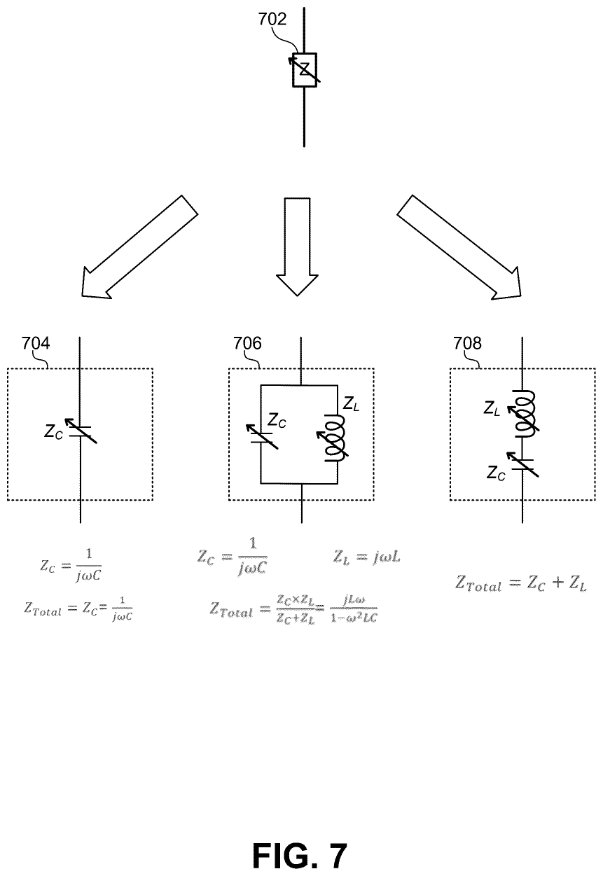

FIG. 7 illustrates different implementations for the variable impedances, according to some embodiments. The variable impedances may be implemented using different circuit elements depending on the type of processing chamber. For example, a variable impedance 702 may be implemented using a variable capacitor 704. Adjusting the value of the variable capacitor 704 may adjust the impedance of the pathway to between the power/ground and the corresponding external mesh. Increasing the value of the variable capacitor 704 may decrease the total impedance and increase the flow of RF power through the corresponding external mesh. Decreasing the value of the variable capacitor 704 may increase the total impedance through that pathway and thus decrease the flow of RF power through the external mesh. The value of the variable capacitor 704 may depend on the characteristics of the plasma process, the substrate, the processing chamber, and other factors. For example, some experimental embodiments have used a variable capacitor 704 in the picofarad range, ranging from 0 pF to 50 pF, to 100 pF, to 250 pF, to 500 pF, or to 1000 pF.

In some embodiments, the variable impedance 702 may be implemented using a parallel combination 706 of a variable capacitor and/or a variable inductor. Similarly, the variable impedance 702 may be omitted using a series combination 708 of a variable capacitor and/or a variable inductor. These values may be adjusted as described above to tune the total impedance as illustrated in FIG. 7. Additionally, these values may be adjusted to allow use of RF power having multiple frequency ranges in the plasma process. For example, some embodiments of the processing chamber may include multiple RF sources, such as a high-frequency RF source and a low-frequency RF source. The high-frequency RF source may be arranged as a top-feed RF source, while the low-frequency RF source may be arranged as a low-frequency RF source, or vice versa. More generally, a first RF source and a second RF source may be used where the first RF source has a higher frequency than the second RF source.

In addition to changing the total impedance of the variable impedance 702, the parallel combination 706 and/or the series combination 708 may be tuned to each of these specific frequencies. For example, the variable capacitance and/or inductance values may be selected such that the variable impedance 702 operates as a short circuit for the higher frequency source and as an open circuit for the low-frequency source, or vice versa. Again, the specific ranges for the variable capacitance and/or variable inductance in the circuits may be dependent on the parameters of the specific process, substrate, and/or chamber. However, experimental values using a nF or pF range for the variable capacitance and a nH or pH range for the variable inductance have been successful.

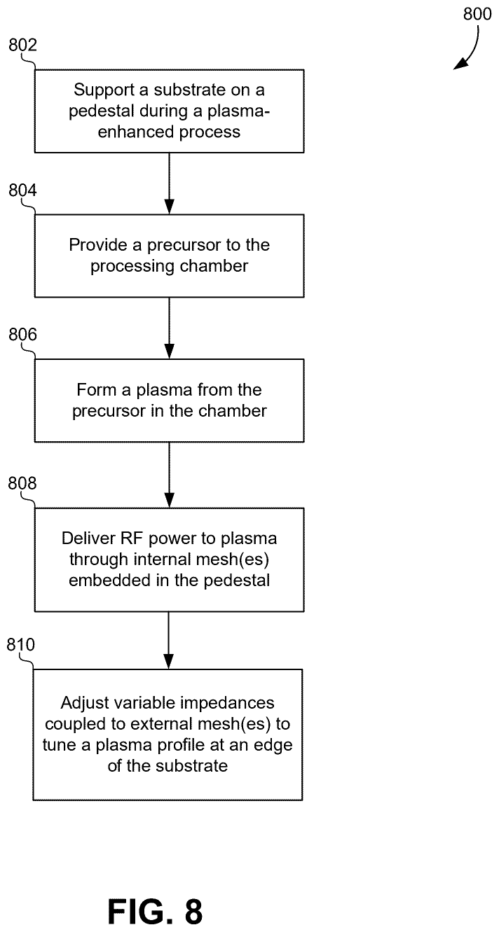

FIG. 8 illustrates a flowchart of a method 800 of tuning plasma profiles during semiconductor processes, according to some embodiments. This method may be performed by any of the semiconductor processing chambers described above in FIGS. 1-6. Additionally, some of the operations in this method may be executed by the controller of the chamber or another computer system. These processor operations may be embodied and stored instructions that are executed by the processor to cause the specified conditions to occur in the processing region.

The method may include supporting a substrate on a pedestal in a semiconductor processing chamber (802). The semiconductor processing chamber may be configured to perform a plasma-enhanced chemical-vapor deposition (PECVD) process that forms a film on a surface of the substrate. For example, the deposition process may include forming alternating oxide and nitride layers in an ONO stack. The deposition process may also include forming a relatively thick layer of silicon oxide (e.g., using a TEOS precursor) that is greater than 10 μm, greater than 15 μm, greater than 20 μm, greater than 25 μm, greater than 30 μm, or larger. The substrate may be formed from silicon, silicon germanium, or other substrate materials. The layers may include IPD layers of ONO layers, including a dielectric material, which may be silicon oxide, in alternating layers with a placeholder material, which may be silicon nitride or polysilicon, for example. In some embodiments, the number of film layers may be very large and may include 10 or more layer pairs, 20 more layer pairs, 50 or more layer pairs, 100 or more layer pairs, and so forth. For example, a height of the semiconductor structure may be more than 10 μm, more than 20 μm, and so forth. The process may also be a plasma-enhanced etch process or any other plasma process.

The method may also include providing a precursor to a semiconductor processing chamber, wherein the precursor comprises a material for the film to be formed on the substrate (804). The precursor may include carrier gases, such as nitrogen, helium, argon, or other noble, inert, or useful precursors. The precursors may also include gas species that include a material for the film, such as TEOS, O₂, N₂O, SiH₄, NH₃, N₂, and so forth. Flow rates for the precursor gas during this step may range from between about 0 sccm to about 13000 sccm. For example, the flow rates may range from between 0 sccm to about 1000 sccm, between 1000 sccm to about 2000 sccm, between 2000 sccm to about 3000 sccm, between 3000 sccm to about 4000 sccm, between 4000 sccm to about 5000 sccm, between 5000 sccm to about 6000 sccm, between 6000 sccm to about 7000 sccm, between 7000 sccm to about 8000 sccm, between 8000 sccm to about 9000 sccm, between 9000 sccm to about 10,000 sccm, between 10,000 sccm to about 11,000 sccm, between 11,000 sccm to about 12,000 sccm, between 12,000 sccm to about 13,000 sccm, greater than 13,00 sccm, and/or any combination of ranges therein.

The method may additionally include forming a plasma from the precursor in the semiconductor processing chamber (806). The temperature within the processing chamber or at the substrate level may be maintained between about 200° C. and about 700° C. in embodiments. The temperature may be maintained above or about 200° C., and may be maintained above or about 250° C., above or about 300° C., above or about 350° C., above or about 400° C., above or about 450° C., above or about 500° C., above or about 550° C., above or about 600° C., above or about 650° C., above or about 700° C., or higher. The pressure may be maintained below or about 15 Torr, and may be maintained below or about 10 Torr, below or about 5 Torr, below or about 4 Torr, below or about 3 Torr, below or about 2 Torr, below or about 1 Torr, below or about 100 mTorr, or lower. In embodiments the pressure may be maintained between about 500 mTorr and about 10 Torr.

The method may further include delivering RF power to plasma through one or more internal meshes embedded in the pedestal (808). The plasma power applied may range from between about 0 W to about 5000 W. For example, the plasma power may range from between about 0 W to about 1000 W, between about 1000 W to about 2000 W, between about 2000 W to about 3000 W, between about 3000 W to about 4000 W, between about 4000 W to about 5000 W, and/or any combination of ranges therein. In some embodiments, a range of frequencies may be associated with the applied RF power. For example, some embodiments may use a high-frequency RF source of approximately 27 MHz. Some embodiments may additionally or alternatively use a low-frequency RF source of approximately 350 kHz. A range of frequencies may also be applied between these two frequencies, such as 13.56 MHz, and other common frequencies or frequency ranges. Some embodiments may also use higher frequency ranges, such as 40 MHz. In note that these embodiments are compatible with any frequency range or sub range between 300 kHz and 40 MHz, or higher. As described above, some implementations may provide multiple frequencies of RF power, such as a high-frequency source and a low-frequency source from the ranges described above.

The method may also include adjusting one or more variable impedances coupled to one or more external meshes to tune a plasma profile at an edge of the substrate (810). The RF power at the periphery of the substrate may be controlled by adjusting the inductance values of the variable inductance is. For example, RF power may be delivered to the internal meshes underneath the substrate. At the edge of the substrate, the external meshes need not be provided with additional RF power. Instead, the external meshes may absorb some of the RF energy or current provided from the internal meshes. Since the external meshes are coupled to ground through the variable impedances, the amount of current or RF energy that is siphoned away from the plasma can be controlled by adjusting the variable impedances. By removing some of the RF energy from the periphery of the substrate, the higher plasma profile characteristics can be reduced until a more uniform plasma profile across the entirety of the substate is achieved.

For example, the system may include a controller that is programmed to dynamically adjust the impedance values of the variable impedances at runtime during the deposition process. For example, the semiconductor processing chamber may operate using a “recipe” that includes recipe steps that adjust the operating conditions or actions taken by the semiconductor processing chamber. The recipe may adjust temperatures, pressures, gas flow rates, gas species present in the processing region, RF power provided to the meshes, DC power provided to the meshes, and so forth. In some embodiments, the recipe may include adjustments to the variable capacitors during the deposition process. For example, RF power may be provided to the internal meshes, and the variable inductance is may be set to a first impedance value during a first portion of the deposition process, and then changed to a second impedance value during a second portion of the deposition process by adjusting the variable impedances in the recipe.

The controller may include one or more processors (e.g., microprocessors, microcontrollers, processor cores, distributed processors, and so forth). The processor(s) may be programmed to perform operations based on instructions stored on one or more memory devices (e.g., cache memory, disk memory, temporary memory, RAM or ROM devices, and so forth). In some embodiments, the instructions may be stored on a non-transitory, tangible, computer-readable medium, such as a physical storage device. The instructions may optionally be stored on a computer program product that is separate and distinct from the processors.

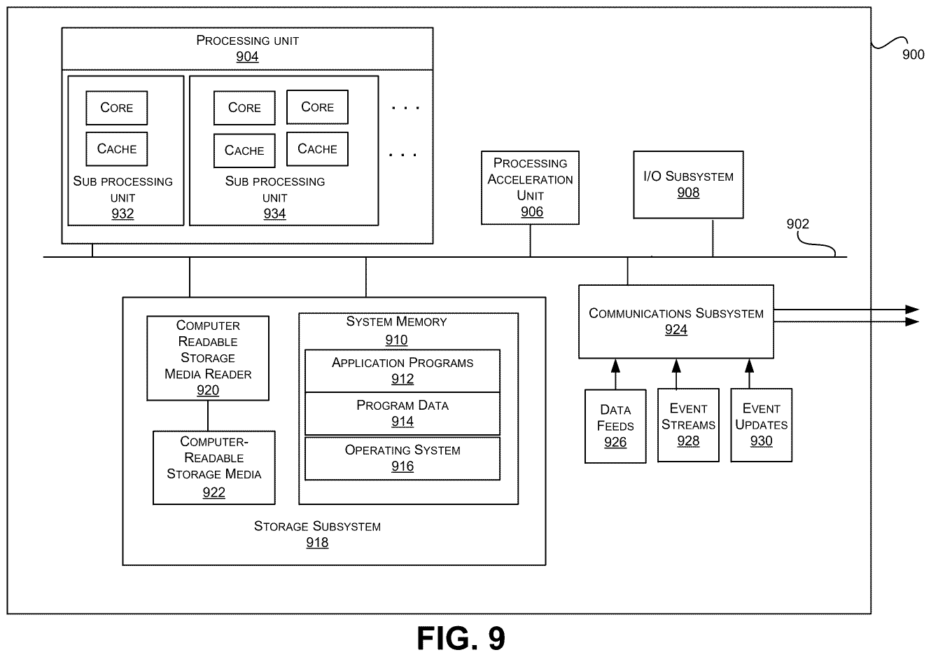

The one or more processors may be implemented in a local controller on the semiconductor processing chamber. The one or more processors may also be distributed on a number of different computing systems. For example, the controller may be part of a local or remote server that controls the operations of the semiconductor processing chamber. The instructions may be distributed between a server and a local controller during the deposition process. An example of a computer system that may be used to implement the controller is illustrated below in FIG. 9.

The sizing of the internal meshes relative to the substrate and the recipe settings for the variable capacitors may be set during the design and/or configuration of the semiconductor processing chamber. Specifically, the design of these components may be tested and adjusted during manufacturing of the semiconductor processing chamber. For example, a substrate may undergo a deposition process in the processing region. The uniformity of the plasma profile characteristics may be monitored using various sensors during the plasma process. For example, optical emission spectroscopy (OES) sensors, reflected power sensors from the plasma, temperature sensors, pressure sensors, and any other sensor type may be used to monitor various characteristics of the plasma profile. The recipe may then be updated to adjust the values for the variable capacitors to improve the film quality. Alternatively, the variable impedances may be adjusted up/down during individual test processes, and the quality or uniformity of the resulting etch or deposition process may be measured using a metrology station on the substrate afterwards. The variable impedances may then be set in future recipes based on the optimal results obtained during the test processes.

For example, some embodiments may set a threshold value for an acceptable amount of variation in one or more of the plasma profile characteristics. This threshold may be less than 25%, less than 20%, less than 15%, less than 10%, less than 5%, less than 2%, and/or less 1%, depending on the requirements of the process. For example, the plasma profile characteristics may be monitored and the variable impedances 454 may be adjusted until the plasma profile varies across the surface of the substrate 402 by less than 10% (or another threshold above). The quality of the film deposition or etch may additionally or alternatively be monitored such that variation across the substrate is minimized. For example, optical spectroscopy may be used to measure a film thickness as it is etched or deposited at various locations on the substrate 402. These thicknesses may then be compared to determine whether the etch or deposition is being performed uniformly across the substrate.

The recipe may then be altered to, for example, reduce the impedance of the route through the external meshes during at least a portion of the process. The recipe may be altered in real time during the process as measurements are received. Alternatively, the recipe may be altered for subsequent substrates. A subsequent substrate may then be processed using the updated recipe, and the resulting film may be measured to determine whether the variation in the etch or deposition at the edge of the substrate has been reduced to below the acceptable threshold. This process may be repeated until the optimal impedance values are determined. This iterative process may generate an optimal set of impedance values. For example, the variable impedances may be increased until less there is less than a 10% variation in the film thickness on the periphery of the substate in comparison to the film thickness on the center of the substrate.

This process may also be used to determine an optimal size for the internal meshes and/or the external meshes. For example, the size and outer diameter of the internal meshes may be reduced and/or the size of the external meshes may be increased until the resulting plasma profile becomes uniform. Alternatively, the density of the external mesh may be increased relative to the internal mesh to improve uniformity. These design-time improvements to the size of the meshes and/or the variable impedances may be carried out individually or in combination to improve the plasma profile uniformity.

It should be appreciated that the specific steps illustrated in FIG. 8 provide particular methods of forming films on substrates according to various embodiments. Other sequences of steps may also be performed according to alternative embodiments. For example, alternative embodiments may perform the steps outlined above in a different order. Moreover, the individual steps illustrated in FIG. 8 may include multiple sub-steps that may be performed in various sequences as appropriate to the individual step. Furthermore, additional steps may be added or removed depending on the particular applications. Many variations, modifications, and alternatives also fall within the scope of this disclosure.

Each of the methods described herein may be implemented by a computer system. Each step of these methods may be executed automatically by the computer system, and/or may be provided with inputs/outputs involving a user. For example, a user may provide inputs for each step in a method, and each of these inputs may be in response to a specific output requesting such an input, wherein the output is generated by the computer system. Each input may be received in response to a corresponding requesting output. Furthermore, inputs may be received from a user, from another computer system as a data stream, retrieved from a memory location, retrieved over a network, requested from a web service, and/or the like. Likewise, outputs may be provided to a user, to another computer system as a data stream, saved in a memory location, sent over a network, provided to a web service, and/or the like. In short, each step of the methods described herein may be performed by a computer system, and may involve any number of inputs, outputs, and/or requests to and from the computer system which may or may not involve a user. Those steps not involving a user may be said to be performed automatically by the computer system without human intervention. Therefore, it will be understood in light of this disclosure, that each step of each method described herein may be altered to include an input and output to and from a user, or may be done automatically by a computer system without human intervention where any determinations are made by a processor. Furthermore, some embodiments of each of the methods described herein may be implemented as a set of instructions stored on a tangible, non-transitory storage medium to form a tangible software product.

FIG. 9 illustrates an exemplary computer system 900, in which various embodiments may be implemented. The system 900 may be used to implement any of the computer systems described above. As shown in the figure, computer system 900 includes a processing unit 904 that communicates with a number of peripheral subsystems via a bus subsystem 902. These peripheral subsystems may include a processing acceleration unit 906, an I/O subsystem 908, a storage subsystem 918 and a communications subsystem 924. Storage subsystem 918 includes tangible computer-readable storage media 922 and a system memory 910.

Bus subsystem 902 provides a mechanism for letting the various components and subsystems of computer system 900 communicate with each other as intended. Although bus subsystem 902 is shown schematically as a single bus, alternative embodiments of the bus subsystem may utilize multiple buses. Bus subsystem 902 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, EtherCAT, and Peripheral Component Interconnect (PCI) bus, which can be implemented as a Mezzanine bus manufactured to the IEEE P1386.1 standard.

Processing unit 904, which can be implemented as one or more integrated circuits (e.g., a conventional microprocessor or microcontroller), controls the operation of computer system 900. One or more processors may be included in processing unit 904. These processors may include single core or multicore processors. In certain embodiments, processing unit 904 may be implemented as one or more independent processing units 932 and/or 934 with single or multicore processors included in each processing unit. In other embodiments, processing unit 904 may also be implemented as a quad-core processing unit formed by integrating two dual-core processors into a single chip.

In various embodiments, processing unit 904 can execute a variety of programs in response to program code and can maintain multiple concurrently executing programs or processes. At any given time, some or all of the program code to be executed can be resident in processor(s) 904 and/or in storage subsystem 918. Through suitable programming, processor(s) 904 can provide various functionalities described above. Computer system 900 may additionally include a processing acceleration unit 906, which can include a digital signal processor (DSP), a special-purpose processor, and/or the like.

I/O subsystem 908 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 900 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 900 may comprise a storage subsystem 918 that comprises software elements, shown as being currently located within a system memory 910. System memory 910 may store program instructions that are loadable and executable on processing unit 904, as well as data generated during the execution of these programs.

Depending on the configuration and type of computer system 900, system memory 910 may be volatile (such as random access memory (RAM)) and/or non-volatile (such as read-only memory (ROM), flash memory, etc.) The RAM typically contains data and/or program modules that are immediately accessible to and/or presently being operated and executed by processing unit 904. In some implementations, system memory 910 may include multiple different types of memory, such as static random access memory (SRAM) or dynamic random access memory (DRAM). In some implementations, a basic input/output system (BIOS), containing the basic routines that help to transfer information between elements within computer system 900, such as during start-up, may typically be stored in the ROM. By way of example, and not limitation, system memory 910 also illustrates application programs 912, which may include client applications, Web browsers, mid-tier applications, relational database management systems (RDBMS), etc., program data 914, and an operating system 916.

Storage subsystem 918 may also provide a tangible computer-readable storage medium for storing the basic programming and data constructs that provide the functionality of some embodiments. Software (programs, code modules, instructions) that when executed by a processor provide the functionality described above may be stored in storage subsystem 918. These software modules or instructions may be executed by processing unit 904. Storage subsystem 918 may also provide a repository for storing data used in accordance with some embodiments.

Storage subsystem 900 may also include a computer-readable storage media reader 920 that can further be connected to computer-readable storage media 922. Together and, optionally, in combination with system memory 910, computer-readable storage media 922 may comprehensively represent remote, local, fixed, and/or removable storage devices plus storage media for temporarily and/or more permanently containing, storing, transmitting, and retrieving computer-readable information.

Computer-readable storage media 922 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information, and which can be accessed by computing system 900.

By way of example, computer-readable storage media 922 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD, and Blu-Ray® disk, or other optical media. Computer-readable storage media 922 may include, but is not limited to, Zip® drives, flash memory cards, universal serial bus (USB) flash drives, secure digital (SD) cards, DVD disks, digital video tape, and the like. Computer-readable storage media 922 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 900.

Communications subsystem 924 provides an interface to other computer systems and networks. Communications subsystem 924 serves as an interface for receiving data from and transmitting data to other systems from computer system 900. For example, communications subsystem 924 may enable computer system 900 to connect to one or more devices via the Internet. In some embodiments communications subsystem 924 can include radio frequency (RF) transceiver components for accessing wireless voice and/or data networks (e.g., using cellular telephone technology, advanced data network technology, such as 3G, 4G or EDGE (enhanced data rates for global evolution), WiFi (IEEE 802.11 family standards, or other mobile communication technologies, or any combination thereof), global positioning system (GPS) receiver components, and/or other components. In some embodiments communications subsystem 924 can provide wired network connectivity (e.g., Ethernet) in addition to or instead of a wireless interface.

In some embodiments, communications subsystem 924 may also receive input communication in the form of structured and/or unstructured data feeds 926, event streams 928, event updates 930, and the like on behalf of one or more users who may use computer system 900.

Additionally, communications subsystem 924 may also be configured to receive data in the form of continuous data streams, which may include event streams 928 of real-time events and/or event updates 930, that may be continuous or unbounded in nature with no explicit end. Examples of applications that generate continuous data may include, for example, sensor data applications, financial tickers, network performance measuring tools (e.g. network monitoring and traffic management applications), clickstream analysis tools, automobile traffic monitoring, and the like.

Communications subsystem 924 may also be configured to output the structured and/or unstructured data feeds 926, event streams 928, event updates 930, and the like to one or more databases that may be in communication with one or more streaming data source computers coupled to computer system 900.

Due to the ever-changing nature of computers and networks, the description of computer system 900 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

As used herein, the terms “about” or “approximately” or “substantially” may be interpreted as being within a range that would be expected by one having ordinary skill in the art in light of the specification. By way of example, these terms may imply a 10% variation above or below a stated value (i.e., “approximately 50” would imply a range between 45 and 55).

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A semiconductor processing chamber comprising:
a pedestal configured to support a substrate during a plasma-enhanced process performed on the substrate;
one or more internal meshes embedded in the pedestal, wherein the one or more internal meshes are configured to deliver radio-frequency (RF) power to a plasma in the semiconductor processing chamber during the plasma-enhanced process;
one or more RF sources configured to deliver the RF power to the one or more internal meshes;
one or more external meshes embedded in the pedestal that encircle the one or more internal meshes; and
one or more variable impedances coupled to the one or more external meshes that tune a plasma profile at an edge of the substrate.

2. The semiconductor processing chamber of claim 1, further comprising:
a controller that is programmed to adjust the one or more variable impedances during the plasma-enhanced process to adjust the RF power delivered to the one or more internal meshes and the one or more external meshes to tune the plasma profile at the edge of the substrate.

3. The semiconductor processing chamber of claim 1, wherein an outer diameter of the one or more internal meshes is less than a diameter of the substrate such that the substrate entirely covers the one or more internal meshes when supported by the pedestal.

4. The semiconductor processing chamber of claim 1, wherein the one or more external meshes together have a ring shape divided into a plurality of sectors that encircles the one or more internal meshes, and an inner diameter of the one or more external meshes is greater than a diameter of the substrate such that the substrate does not cover the one or more external meshes when supported by the pedestal.

5. The semiconductor processing chamber of claim 1, wherein the one or more internal meshes is a single mesh that also functions as a monopolar electrostatic chuck.

6. The semiconductor processing chamber of claim 1, wherein the one or more internal meshes comprises a two hemispherical meshes that also function as a bipolar electrostatic chuck.

7. The semiconductor processing chamber of claim 1, wherein the one or more external meshes comprises three or more meshes that do not function as an electrostatic chuck.

8. The semiconductor processing chamber of claim 1, wherein the one or more external meshes are electrically coupled to ground through the one or more variable impedances, such that adjusting the one or more variable impedances tunes an amount of the RF power provided to the one or more internal meshes that is shunted to ground through the one or more external meshes.

9. The semiconductor processing chamber of claim 1, wherein the one or more external meshes are electrically coupled to one or more second RF sources through the one or more variable impedances.

10. The semiconductor processing chamber of claim 1, wherein the plasma-enhanced process comprises a plasma-enhanced chemical-vapor deposition (PECVD) process that forms a film on a surface of the substrate.

11. A method of tuning plasma profiles during semiconductor processes, the method comprising:
supporting a substrate on a pedestal in a semiconductor processing chamber, wherein the semiconductor processing chamber is configured to perform a plasma-enhanced chemical-vapor deposition (PECVD) process that forms a film on a surface of the substrate;
providing a precursor to a semiconductor processing chamber, wherein the precursor comprises a material for the film to be formed on the substrate;
forming a plasma from the precursor in the semiconductor processing chamber;
delivering radio-frequency (RF) power to plasma through one or more internal meshes embedded in the pedestal; and
adjusting one or more variable impedances coupled to one or more external meshes to tune a plasma profile at an edge of the substrate.

12. The method of claim 11, wherein a variable impedance in the one or more variable impedances comprises a variable capacitor with a range of between 0 nF and 100 nF.

13. The method of claim 11, wherein:
the RF power provided to the plasma comprises a first frequency and a second frequency where the first frequency is higher than the second frequency;
a variable impedance in the one or more variable impedances comprises a variable capacitor in series with an inductor, and the variable impedance is tuned to approximate an open circuit for the second frequency and a short-circuit for the first frequency.

14. The method of claim 11, wherein:
the RF power provided to the plasma comprises a first frequency and a second frequency where the first frequency is higher than the second frequency;
a variable impedance in the one or more variable impedances comprises a variable capacitor in parallel with an inductor, and the variable impedance is tuned to approximate an open circuit for the second frequency and a short-circuit for the first frequency.

15. The method of claim 11, wherein adjusting the one or more variable impedances coupled to one or more external meshes to tune the plasma profile at the edge of the substrate comprises:
adjusting the one or more variable impedances until a variation of the plasma profile at the edge of the substrate has a variation of less than 10% of a plasma profile at a center of the substrate.

16. The method of claim 11, further comprising:
monitoring a characteristic of the plasma that is indicative of the plasma profile at the edge of the substrate during the process; and
adjusting the one or more variable impedances to tune a plasma profile at an edge of the substrate in response to monitoring the characteristic of the plasma until the plasma profile at the edge of the substrate is within a predetermined range during the process.

17. A semiconductor processing chamber comprising:
a pedestal configured to support a substrate during a plasma-enhanced process performed on a substrate;
one or more internal meshes embedded in the pedestal, wherein the one or more internal meshes are configured to deliver a first radio-frequency (RF) power to a plasma in the semiconductor processing chamber during the plasma-enhanced process;
one or more first RF sources configured to deliver the first RF power to the one or more internal meshes;
one or more external meshes embedded in the pedestal that encircle the one or more internal meshes; and
one or more second RF sources coupled to the one or more external meshes, where in a phase difference between the one or more first RF sources and the one or more second RF sources is adjustable to tune a plasma profile at an edge of the substrate.

18. The semiconductor processing chamber of claim 17, further comprising:
a controller that is programmed to adjust the phase difference between the one or more first RF sources and the one or more second RF sources to tune a plasma profile at an edge of the substrate during the plasma-enhanced process.

19. The semiconductor processing chamber of claim 17, wherein the phase difference between the one or more first RF sources and the one or more second RF sources comprises the one or more first RF sources lagging behind the one or more second RF sources by 90°.

20. The semiconductor processing chamber of claim 17, wherein the phase difference between the one or more first RF sources and the one or more second RF sources comprises the one or more first RF sources lagging behind the one or more second RF sources by 180°.
